(19) United States
(12) Patent Application Publication
(10) Pub. No.: US 2008/0054978 A1
(43) Pub. Date: Mar. 6, 2008

(54) Level-determining device and method of pulse width modulation signal

(75) Inventors: Magellan Chiu, Taoyuan Hsien (TW); Venson Kuo, Taoyuan Hsien (TW)

Correspondence Address: BIRCH STEWART KOLASCH & BIRCH, PO BOX 747, FALLS CHURCH, VA, 22040-0747, US

(73) Assignee: DELTA ELECTRONICS, INC.

(21) Appl. No.: 11/889,021

(22) Filed: Aug. 8, 2007

(30) Foreign Application Priority Data
Aug. 30, 2006 (TW) 095131980

(51) Int. Cl. H03L 5/00

(52) U.S. Cl. 327/306

(57) ABSTRACT

A level-determining device of pulse width modulation (PWM) signal includes a PWM signal generating circuit, a reference voltage generating circuit and a determining circuit. The PWM signal generating circuit generates a first PWM signal. The reference voltage generating circuit generates a reference voltage signal. The determining circuit is respectively electrically connected to the PWM signal generating circuit and the reference voltage generating circuit for determining high level or low level of the first PWM signal in accordance with the reference voltage signal for generating a second PWM signal.

### CROSS REFERENCE TO RELATED APPLICATIONS

This non-provisional application claims priority under 35 U.S.C. §119(a) on Patent Application No. 095131980 filed in Taiwan, Republic of China on Aug. 30, 2006, the entire contents of which are hereby incorporated by reference.

### BACKGROUND OF THE INVENTION

1. Field of Invention

The present invention relates to a determining device and a determining method, and more particularly to a level-determining device of pulse width modulation (PWM) signal and a determining method thereof.

2. Related Art

Due to the development of the electronic technique, the PWM signal is frequently applied to control the electronic components.

Please referring to FIG. 1, the PWM technique is a method with digital coding level of analog signal. That is, the PWM technique transforms analog signal into square wave signal of high level and low level. The essential parameters of the PWM signal includes a high level V_{H}, a low level V_{L} and a duty cycle D representing a ratio of the time of the high level V_{H} during a square wave cycle T. The ratio is usually represented by percentage.

Please referring to FIG. 2, high level or low level of a PWM signal Sp01 generated from a PWM signal generating circuit 12 is determined by a transistor-transistor-logic (TTL) circuit 11 in the prior art. In general, the maximum determining voltage is 0.8V while the TTL circuit 11 is determining as the low level. That is, the low level of the PWM signal Sp01 may be greater than 0.8V if the PWM signal Sp01 is interfered with noise in the signal-transmission, and then the PWM signal Sp01 may be incorrectly determined as the high level or failed to determine by the TTL circuit 11. Thus, the TTL circuit 11 or its next stage circuit performs an incorrect operation.

Therefore, it is an important subject to provide a level-determining device and a method which possessing better endurance to noise so that the level of the PWM signal can prevent from being misjudged.

### SUMMARY OF THE INVENTION

In view of the foregoing, the present invention is to provide a level-determining device and a method thereof for adjusting the high level or low level of PWM signal in accordance with the various systems.

To achieve the above, a level-determining device of PWM signal according to the present invention includes a PWM signal generating circuit, a reference voltage generating circuit and a determining circuit. The PWM signal generating circuit generates a first PWM signal. The reference voltage generating circuit generates a reference voltage signal. The determining circuit is electrically connected to the PWM signal generating circuit and the reference voltage generating circuit for determining high level or low level of the first PWM signal in accordance with the reference voltage signal to generate a second PWM signal.

To achieve the above, a level-determining method of PWM signal according to the present invention includes the following steps. To generate a first PWM signal by a PWM signal generating circuit. To generate a reference voltage signal by a reference voltage generating circuit. To determine high level or low level of the first PWM signal in accordance with the reference voltage signal for generating a second PWM signal by a determining circuit.

As mentioned above, the level-determining device of PWM signal and its method that determine high level or low level of the PWM signal in accordance with the voltage signal, which generated by the reference voltage generating circuit, by the determining circuit. The voltage signal can be adjusted in accordance with the requirement of various systems so that the level of the PWM signal is accurately determined. Compared to the prior art, the level-determining device and its method of the present invention have the advantage of preventing the level of the PWM signal from being misjudged.

### BRIEF DESCRIPTION OF THE DRAWINGS

The present invention will become more fully understood from the detailed description given hereinbelow illustration only, and thus is not limitative of the present invention, and wherein:

FIG. 1 is a schematic diagram showing a conventional PWM signal;

FIG. 2 is a schematic diagram showing a conventional level-determining device of the PWM signal;

FIG. 3 is a schematic diagram showing a preferred embodiment of a level-determining device of PWM signal according to the present invention;

FIGS. 4A and 4B are schematic diagrams showing the various reference voltage generating circuits of the level-determining device according to a preferred embodiment of the present invention; and

FIG. 5 is a flow chart showing a level-determining method.of PWM signal according to a preferred embodiment of the present invention.

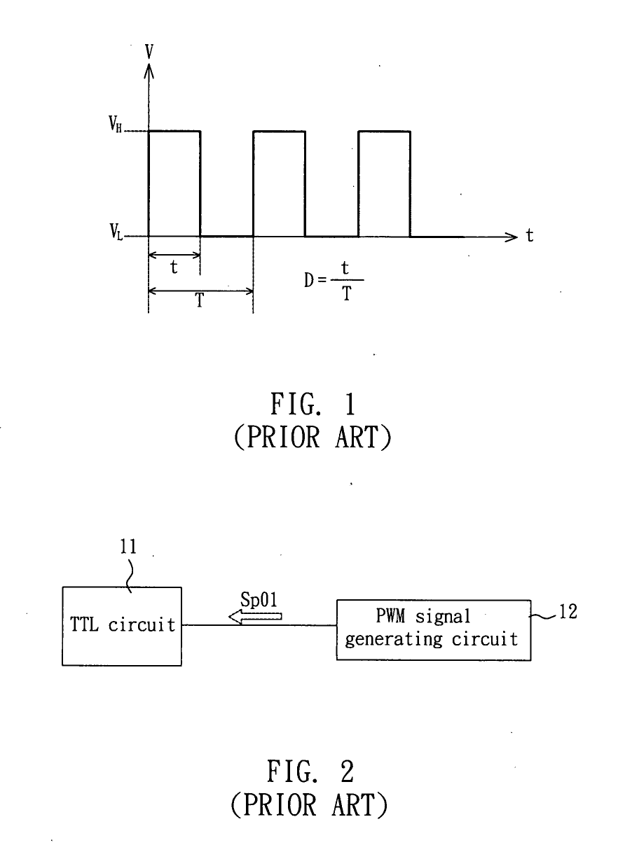

### DETAILED DESCRIPTION OF THE INVENTION

The present invention will be apparent from the following detailed description, which proceeds with reference to the accompanying drawings, wherein the same references relate to the same elements.

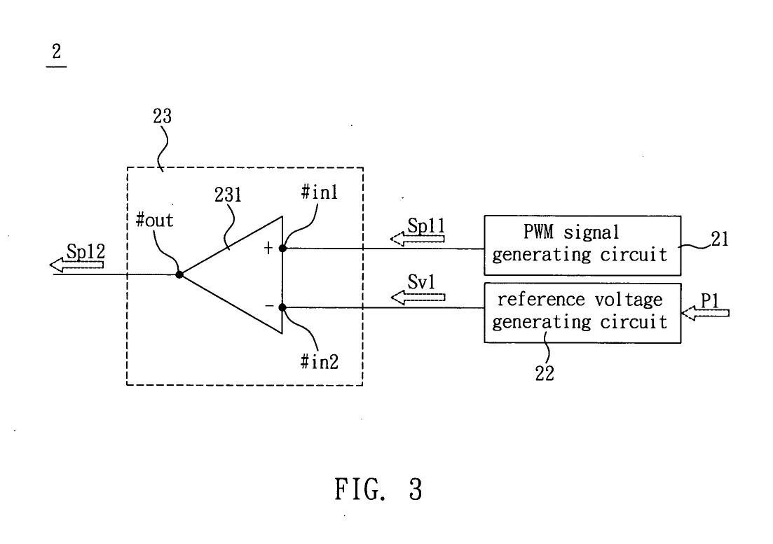

Please referring to FIG. 3, a preferred embodiment of a level-determining device 2 of PWM signal according to the present invention includes a PWM signal generating circuit 21, a reference voltage generating circuit 22 and a determining circuit 23.

The PWM signal generating circuit 21 generates a first PWM signal Sp11. The frequency, duty cycle and level of the PWM signal Sp11 can be adjusted in accordance with the requirement of different systems. The first PWM signal Sp11 can be generated by an analog circuit or a digital circuit.

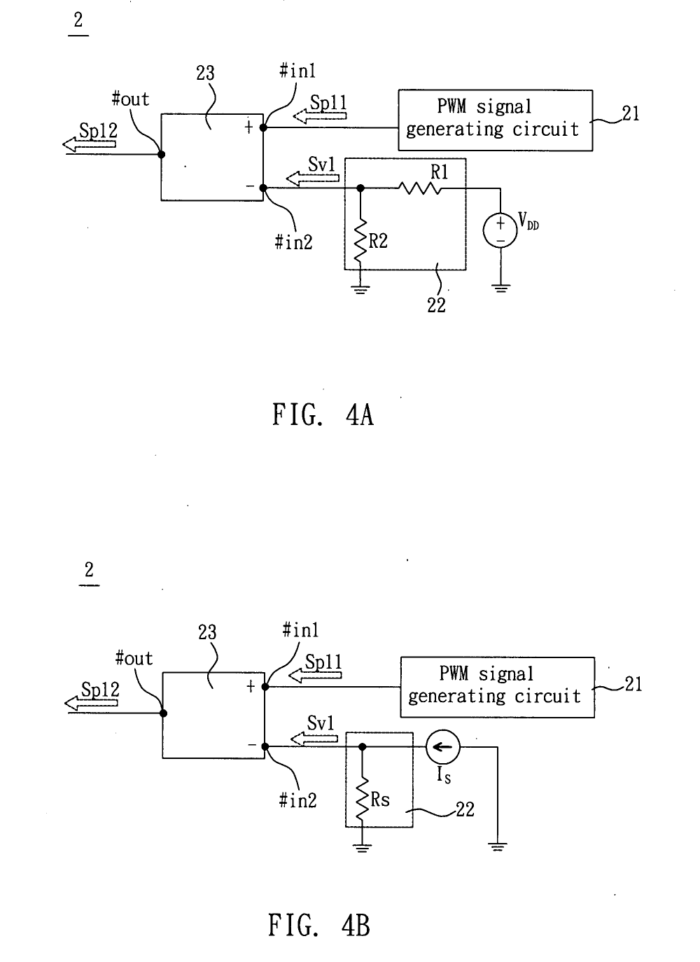

The reference voltage generating circuit 22 generates a reference voltage signal Sv1 in accordance with a power signal P1. Please referring to FIG. 4A, the reference voltage generating circuit 22 includes a voltage divider when the power signal P1, which generated by a voltage source, is a voltage V_{DD}. In this embodiment, the voltage divider has a first resistor R1 and a second resistor R2, and the power signal P1 is transformed into the reference voltage signal Sv1 by the first resistor R1 and the second resistor R2. The reference voltage signal Sv1 can be obtained as following equation:

$$Sv 1 = \frac{R 2 \times VDD}{R 1 + R 2}$$

Please referring to FIG. 4B, the reference voltage generating circuit 22 includes a resistor Rs when the power signal P1, which generated by a current source, is a current Is. The reference voltage signal Sv1 is obtained as a voltage drop generated after the current Is flowing through the resistor Rs.

Please referring to FIG. 3, the determining circuit 23 is electrically connected to the PWM signal generating circuit 21 and the reference voltage generating circuit 22, respectively. The determining circuit 23 determines high level or low level value of the first PWM signal Sp11 in accordance with the reference voltage signal Sv1 for generating a second PWM signal Sp12. The determining circuit 23 includes a comparator 231 or an operating amplifier. The determining circuit 23 includes the comparator 231 is exemplary in this embodiment.

In this embodiment, the comparator 231 has a positive input terminal #in1, a negative input terminal #in2 and an output terminal #out. The positive input terminal #in1 is electrically connected to the PWM signal generating circuit 21, and the first PWM signal Sp11 is input into the comparator 231 through the positive input terminal #in1. The negative input terminal #in2 is electrically connected to the reference voltage generating circuit 22, and the reference voltage signal Sv1 is input into the comparator 231 through the negative input terminal #in2.

In general, the characteristics of the comparator outputs high level from the output terminal when the level of the positive input terminal is greater than the level of the negative input terminal, and output low level from the output terminal when the level of the positive input terminal is less than the negative input terminal. Therefore, the level-determining device 2 of PWM signal according to the present invention can adjust the reference voltage signal Sv1 in accordance with various systems so that the determining circuit 23 can accurately determine high level or low level of the first PWM signal Sp11 for generating the second PWM signal Sp12. Thus, the determining circuit 23 can prevent the level of the PWM signal from being incorrectly determined with noise.

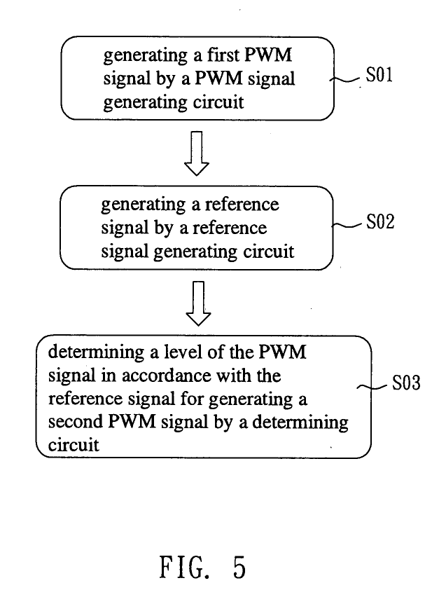

In addition, please referring to FIG. 5, a preferred embodiment of a level-determining method of PWM signal according to the present invention includes the following steps. Step S01 is to generate a first PWM signal by a PWM signal generating circuit. Step S02 is to generate a reference voltage signal by a reference voltage generating circuit. Step S03 is to determine high level or low level of the first PWM signal in accordance with the reference voltage signal for generating a second PWM signal by a determining circuit. The level-determining method of PWM signal is illustrated in the above-mentioned embodiment, so the detailed descriptions are omitted for conciseness.

In summary, the level-determining device of PWM signal and its method that determine high level or low level of the PWM signal in accordance with the voltage signal, which generated by the reference voltage generating circuit, by the determining circuit. The voltage signal can be adjusted in accordance with the requirement of different systems so that the level of the PWM signal is accurately determined. Compared to the prior art, the level-determining device and the method thereof have the advantage of preventing the level of the PWM signal from being misjudged.

Although the present invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the present invention.

What is claimed is:

1. A level-determining device of pulse width modulation (PWM) signal, comprising:
a PWM signal generating circuit generating a first PWM signal;
a reference voltage generating circuit generating a reference voltage signal; and
a determining circuit electrically connected to the PWM signal generating circuit and the reference voltage generating circuit, and determining a level of the first PWM signal in accordance with the reference voltage signal for generating a second PWM signal.

2. The level-determining device according to claim 1, wherein the determining circuit comprises a comparator.

3. The level-determining device according to claim 1, wherein the determining circuit comprises an operational amplifier.

4. The level-determining device according to claim 1, wherein the reference voltage generating circuit generates the reference voltage signal in accordance with a power signal input from exterior.

5. The level-determining device according to claim 4, wherein the power signal is a voltage or a current.

6. The level-determining device according to claim 5, wherein the reference voltage generating circuit comprises a voltage divider generating the reference voltage signal.

7. The level-determining device according to claim 5, wherein the voltage divider comprises a first resistor and a second resistor.

8. The level-determining device according to claim 5, wherein the reference voltage generating circuit comprises a resistor generating the reference voltage signal in accordance with the current.

9. The level-determining device according to claim 1, wherein the PWM signal generating circuit is an analog circuit or a digital circuit.

10. A level-determining method of PWM signal comprising steps of:
generating a first PWM signal by a PWM signal generating circuit;
generating a reference voltage signal by a reference voltage generating circuit; and
determining a level of the first PWM signal in accordance with the reference voltage signal for generating a second PWM signal by a determining circuit.

11. The level-determining method according to claim 10, further comprising a step of inputting a power signal into the reference voltage generating circuit.

12. The level-determining method according to claim 11, wherein the reference voltage signal is generated by the power signal through a voltage divider or a resistor.

13. The level-determining method according to claim 10, wherein the reference voltage signal and the first PWM signal are inputted into a comparator of the determining circuit for generating the second PWM signal.

14. The level-determining method according to claim 10, wherein the reference voltage signal and the first PWM signal are inputted into an operating amplifier of the determining circuit for generating the second PWM signal.

15. The level-determining method according to claim 10, wherein the PWM signal generating circuit is an analog circuit or a digital circuit.
